(19) United States
(12) Patent Application Publication
(10) Pub. No.: US 2022/0148928 A1
(43) Pub. Date: May 12, 2022

(54) DETECTION METHOD AND DETECTION STRUCTURE FOR DISPLAY BACKPLANE

(71) Applicant: CHONGQING KONKA PHOTOELECTRIC TECHNOLOGY RESEARCH INSTITUTE CO., LTD., Chongqing (CN)

(72) Inventors: Ruilin XU, Chongqing (CN); CHIEN-HUNG LIN, Chongqing (CN)

(21) Appl. No.: 17/533,657

(22) Filed: Nov. 23, 2021

Related U.S. Application Data
(63) Continuation of application No. PCT/CN2021/087089, filed on Apr. 14, 2021.

(30) Foreign Application Priority Data
Nov. 11, 2020 (CN) 202011257133.9

(51) Int. Cl. H01L 21/66; H01L 25/16

(52) U.S. Cl. CPC H01L 22/20; H01L 24/83; H01L 25/167

(57) ABSTRACT

A detection method and a detection structure for a display backplane is provided in the disclosure. The detection method includes the following. The display backplane is provided. The display backplane is provided with a contact electrode pair. A detection structure is provided. The detection structure includes a light-emitting element and a detection circuit configured to conduct an electrical signal to the light-emitting element. The detection structure is assembled on the display backplane to connect the detection circuit to the contact electrode pair. A drive electrical signal is outputted to the contact electrode pair. If the light-emitting element does not emit light, the contact electrode pair is determined as a fault point.

### CROSS-REFERENCE TO RELATED APPLICATION(S)

This application is a continuation of International Application No. PCT/CN2021/087089, filed Apr. 14, 2021, which claims priority to Chinese Patent Application No. 202011257133.9, filed Nov. 11, 2020, the entire disclosures of which are hereby incorporated by reference.

### TECHNICAL FIELD

This disclosure relates to the technical field of display devices, and more particularly to a detection method and a detection structure for a display backplane.

### BACKGROUND

With the rapid development of display technology and the advancement of light-emitting diode (LED) production technology, displays have shown a development trend of high integration and low cost. As a new generation of display technology, Micro LED has higher brightness, better luminous efficiency, and lower power consumption than the existing organic light-emitting diode (OLED) technology, which has great application prospects. In a current production process of thin film transistor liquid crystal displays (TFT-LCD), due to process reasons, there may be defects on the display backplane, which will affect the subsequent chip lighting effect. Therefore, in the common production process, the backplane of the display panel needs to be inspected before the display panel is formed.

However, existing detection methods are to perform detection by lighting the chip after the mass transfer. In this case, after finding a fault point, the chip needs to be removed first, then the display backplane is repaired, and at last the chip is welded again. This process are cumbersome and requires complicated operations.

Therefore, the related art needs to be improved.

### SUMMARY

According to the disclosure, a detection method for a display backplane is provided. The method includes the following. The display backplane is provided, where the display backplane is provided with a contact electrode pair. A detection structure is provided, where the detection structure includes a light-emitting element and a detection circuit configured to conduct an electrical signal to the light-emitting element. The detection circuit is connected with the contact electrode pair by assembling the detection structure on the display backplane. A drive electrical signal is outputted to the contact electrode pair. The contact electrode pair is determined as a fault point on condition that the light-emitting element does not emit light.

In some implementations, the detection method further includes the following. After the drive electrical signal is outputted to the contact electrode pair, the contact electrode pair is determined to be normal on condition that the light-emitting element emits light.

In some implementations, the detection structure is assembled on the display backplane as follows. A connection layer is formed by applying glue to the display backplane on one side provided with the contact electrode pair. The detection structure is covered on the connection layer to fix the detection structure to the display backplane through the connection layer.

In some implementations, the detection method further includes the following. The display backplane is flushed with a flushing agent to eliminate the connection layer and the detection structure is removed.

In some implementations, the contact electrode pair is embodied as multiple contact electrode pairs arranged in a rectangular array. The detection circuit is embodied as multiple detection circuits. The light-emitting element is embodied as multiple light-emitting elements. Each of the multiple detection circuits is connected to at least one of the multiple light-emitting elements. The detection circuit is connected with the contact electrode pair as follows. The display backplane is covered with the detection structure to arrange the multiple detection circuits along a width direction of the display backplane, where each detection circuit is connected with one column of contact electrode pairs along a length direction of the display backplane.

In some implementations, the glue is applied to the display backplane on one side provided with the contact electrode pair as follow. The glue is applied to the display backplane at positions between any two neighboring rows of contact electrode pairs of the multiple contact electrode pairs.

In some implementations, the drive electrical signal is outputted to the contact electrode pair as follow. The drive electrical signal is outputted to the multiple contact electrode pairs row-by-row.

In some implementations, the detection structure is assembled on the display backplane as follows. The display backplane is covered with the detection structure on one side of the display backplane provided with the contact electrode pair. The detection structure is pressed in a direction of covering to fix the detection structure to the display backplane.

In some implementations, a first positioning structure is disposed on one side of the detection structure towards the display backplane and a second positioning structure is disposed on one side of the display backplane at a position opposite to the first positioning structure. The detection circuit is aligned with the contact electrode pair when the first positioning structure is aligned with the second positioning structure. Before connecting the detection circuit with the contact electrode pair, the following is further executed. The detection structure is moved to a position above the display backplane to align the first positioning structure with the second positioning structure.

According to the disclosure, a detection structure for a display backplane is provided. The detection structure is configured to implement any of the detection method described above. The detection structure includes a substrate, a light-emitting element, and a detection circuit. The light-emitting element is disposed on the substrate. The detection circuit is disposed on the substrate and connected with the light-emitting element. The detection circuit is configured to receive a drive electrical signal and transmit the drive electrical signal to the light-emitting element.

In some implementations, the detection circuit includes a first detection line and a second detection line. The first detection line is configured to conduct a positive electrical signal to the light-emitting element and the second detection line is configured to conduct a negative electrical signal to the light-emitting element. Alternatively, the second detection line is configured to conduct the positive electrical signal to the light-emitting element and the first detection line is configured to conduct the negative electrical signal to the light-emitting element.

In some implementations, the detection circuit is embodied as multiple detection circuits arranged side-by-side on the substrate.

In some implementations, the detection circuit and the light-emitting element are each located at one side of the substrate, where the substrate defines a hole and the detection circuit is connected with the light-emitting element through the hole.

According to the disclosure, a detection method for a display backplane is provided. The method includes the following. The display backplane is provided, where the display backplane is provided with contact electrode pairs. A detection structure is provided, where the detection structure includes a light-emitting element and a detection circuit configured to conduct an electrical signal to the light-emitting element. The detection circuit is connected with the contact electrode pairs by assembling the detection structure on the display backplane. A drive electrical signal is outputted to the contact electrode pairs row-by-row. A contact electrode pair is determined as a fault point on condition that the drive electrical signal is outputted to the contact electrode pair and the light-emitting element does not emit light.

### BRIEF DESCRIPTION OF THE DRAWINGS

To describe technical solutions in implementations of this disclosure or in the related art more clearly, the following briefly introduces accompanying drawings required for describing the implementations or the related art. Apparently, the accompanying drawings in the following description only illustrate some implementations of this disclosure. Those of ordinary skill in the art may also obtain other drawings based on these accompanying drawings without creative efforts.

FIG. 1 is a schematic structural diagram illustrating an LED chip according to implementations.

FIG. 2 is a schematic structural diagram illustrating a display backplane according to implementations.

FIG. 3 is a schematic structural diagram illustrating a portion of a display panel according to implementations.

FIG. 4 is a schematic flow chart illustrating a detection method according to implementations.

FIG. 5 is a perspective view illustrating portions of a detection structure and a display backplane according to implementations.

FIG. 6 is a side view in a direction y in FIG. 5.

FIG. 7 is a side view in a direction x in FIG. 5.

FIG. 8 is a schematic structural diagram illustrating a portion of a detection structure according to implementations.

FIG. 9 is a schematic structural diagram illustrating a portion of a display backplane according to implementations.

FIG. 10 is another perspective view illustrating portions of a detection structure and a display backplane according to implementations.

In these figures:

10: detection structure; 11: substrate; 111: hole; 12: light-emitting element; 13: detection circuit; 131: first detection line; 132: second detection line; 20: display backplane; 21: contact electrode pair; 211: first contact electrode; 212: second contact electrode; 22: planarization layer; 23: circuit layer; 24: lower substrate; 30: connection layer.

### DETAILED DESCRIPTION

In order to enable those skilled in the art to better understand solutions of the disclosure, technical solutions in implementations of the disclosure will be described clearly and completely hereinafter with reference to the accompanying drawings in the implementations of the disclosure. Apparently, the described implementations are merely some rather than all implementations of the disclosure. All other implementations obtained by those of ordinary skill in the art based on the implementations of the disclosure without creative efforts shall fall within the protection scope of the disclosure.

In the related art, a Micro-LED display, as a new screen display, has advantages such as high stability, long service life, and improved operating temperature. Meanwhile, the Micro-LED display also inherits advantages from LED, which include low power consumption, high color saturation, high response speed, and high contrast. The Micro-LED display has wide prospects of application.

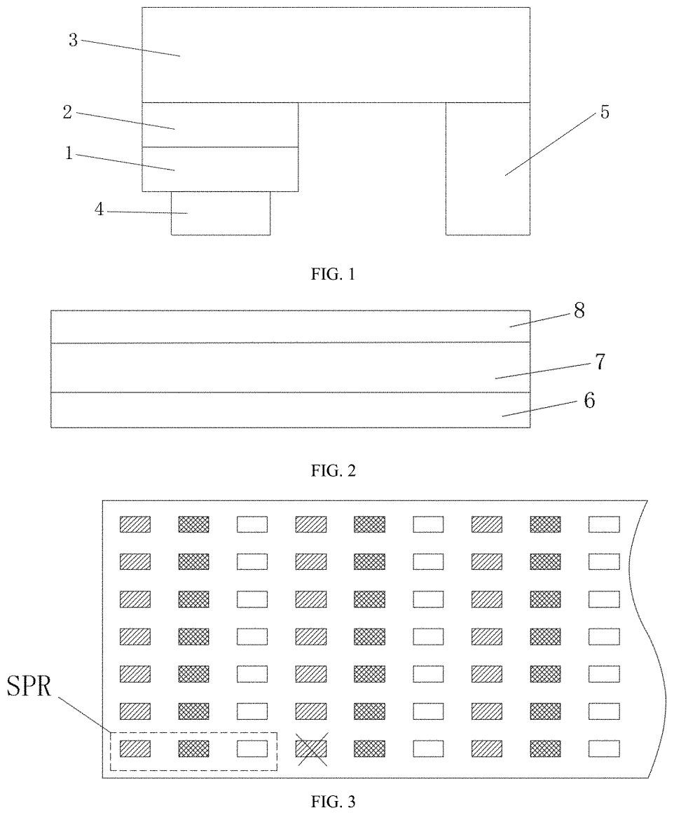

As illustrated in FIG. 1, the Micro-LED display generally adopts a LED flip chip. A first semiconductor layer 1 may be an N/P-type doped GaN layer. A light-emitting layer 2 may be a quantum well layer. A second semiconductor layer 3 may be a P/N-type doped GaN layer. A first electrode 4 and a second electrode 5 are made of a conductive material such as a metal. When an electrical signal is applied to the first electrode 4 and the second electrode 5, electrons inside an N-type semiconductor collide and recombine with holes inside a P-type semiconductor to produce photons in the light-emitting layer to excite energy in form of photons. The first electrode 4 and the second electrode 5 may be made of aluminum (Al), platinum (Pt), palladium (Pd), argentum (Ag), magnesium (Mg), aurum (Au), nickel (Ni), neodymium (Nd), iridium (Lr), chromium (Cr), lithium (Li), calcium (Ca), molybdenum (Mo), titanium (Ti), wolframium (W), or cuprum (Cu), etc.

As illustrated in FIG. 2, generally, a display backplane carrying an LED chip may include a display substrate 6, a circuit layer 7, and a planarization layer 8. The display substrate 6 may be made of a transparent glass material, such as silicon dioxide (SiO₂), and may also be made of a transparent plastic material, such as polyethersulfone (PES), polyacrylate (PAR), polyetherimide (PEI), polyethylene-naphthalate (PEN), polyethylene-terephthalate (PET), polyphenylene sulfide (PPS), polyallylate, polyimide, polycarbonate (PC), cellulose triacetate (TAC), cellulose acetate propionate (CAP), etc.

The circuit layer 7 includes a drive circuit for driving the LED chip. The drive circuit may include, for example, a thin film transistor (TFT), a gate line, or a signal line, etc.

The planarization layer 8 covers the circuit layer, which can eliminate a step difference on the circuit layer 7 and flatten the circuit layer 7. The planarization layer 8 may be made of an organic material, such as polymethylmethacrylate (PMMA) or polystyrene (PS), a polymer derivative having a phenol group, acryl-based polymer, imide-based polymer, aryl ether-based polymer, amide-based polymer, fluorine-based polymer, p-xylene-based polymer, vinyl alcohol-based polymer, or a blend thereof

The drive circuit may include a first contact electrode and a second contact electrode, which may be disposed on a surface of the planarization layer 8 and be connected with the signal line or the gate line (the gate line can transmit an on/off signal to the TFT) in the circuit layer 7 through a filling material in holes on the planarization layer 8. The first contact electrode and the second contact electrode are bonded with the first electrode and the second electrode on the LED chip respectively. The first contact electrode, the second contact electrode, the filling material in the holes, the signal line, or the gate line may be made of aluminum (Al), platinum (Pt), palladium (Pd), argentum (Ag), magnesium (Mg), aurum (Au), nickel (Ni), neodymium (Nd), iridium (Ir), chromium (Cr), lithium (Li), calcium (Ca), molybdenum (Mo), titanium (Ti), wolframium (W), cuprum (Cu), etc.

The structure of a Micro-LED display panel can include the following. The circuit layer may include a buffer layer, a gate insulating layer, an interlayer insulating layer, the TFT, and a gate line contact point, etc.

The buffer layer is disposed on the substrate and provides a substantially flat surface on the substrate to reduce or avoid invasion of a foreign material or moisture to the substrate. The buffer layer may be made of an inorganic material such as silicon dioxide (SiO₂), silicon nitride (SiNx), silicon oxynitride (SiON), aluminum oxide (Al₂O₃), aluminum nitride (AlN), titanium dioxide (TiO₂), or titanium nitride (TiN). The buffer layer may also be made of an organic material such as polyimide, polyester, or propene.

The TFT may include an active layer, a gate, a source, and a drain. The TFT may be a top-gate thin film transistor (the TFT may also be a bottom-gate thin film transistor in fact). The active layer may be made of a semiconductor material such as amorphous silicon or polycrystalline silicon. The active layer may also be made of other materials such as an organic semiconductor material or an oxide semiconductor material.

The gate/source/drain may be made of a low resistance metallic material such as aluminum (Al), platinum (Pt), palladium (Pd), argentum (Ag), magnesium (Mg), aurum (Au), nickel (Ni), neodymium (Nd), iridium (Ir), chromium (Cr), lithium (Li), calcium (Ca), molybdenum (Mo), titanium (Ti), wolframium (W), cuprum (Cu), etc.

The gate insulating layer, used to insulate the gate and the active layer, may be made of an inorganic material such as SiO₂, SiNx, SiON, Al₂O₃, TiO₂, tantalum oxide (Ta₂O₅), hafnium oxide (HfO₂) or zinc oxide (ZnO₂), etc.

The interlayer insulating layer is used to insulate the source and the gate or insulate the drain and the gate. The interlayer insulating layer may be made of an inorganic material such as SiO₂, SiNx, SiON, Al₂O₃, TiO₂, Ta₂O₅, HfO₂ or ZnO₂, etc.

The gate line contact point may be formed on one of multiple insulating films disposed below the planarization layer and may be formed above the interlayer insulating layer or the gate insulating layer.

In the related art, the Micro-LED display panel has several pixel regions (SPR). Each of the SPR includes a red LED chip, a blue LED chip, and a green LED chip. As illustrated in FIG. 3, in a manufacturing process of a display, the red, blue, and green LED chips may be transferred from respective growth substrates to the display backplane. However, if any of the LED chips is damaged or in poor contact (as illustrated at a position “X” in FIG. 3), a fault point will appear on the display backplane after a transfer process, which will influence an imaging effect.

In view of the drawbacks of the related art, this disclosure provides a detection method and a detection structure for a display backplane, aiming to quickly detect the fault point on the display backplane to facilitate timely repairing of the display backplane.

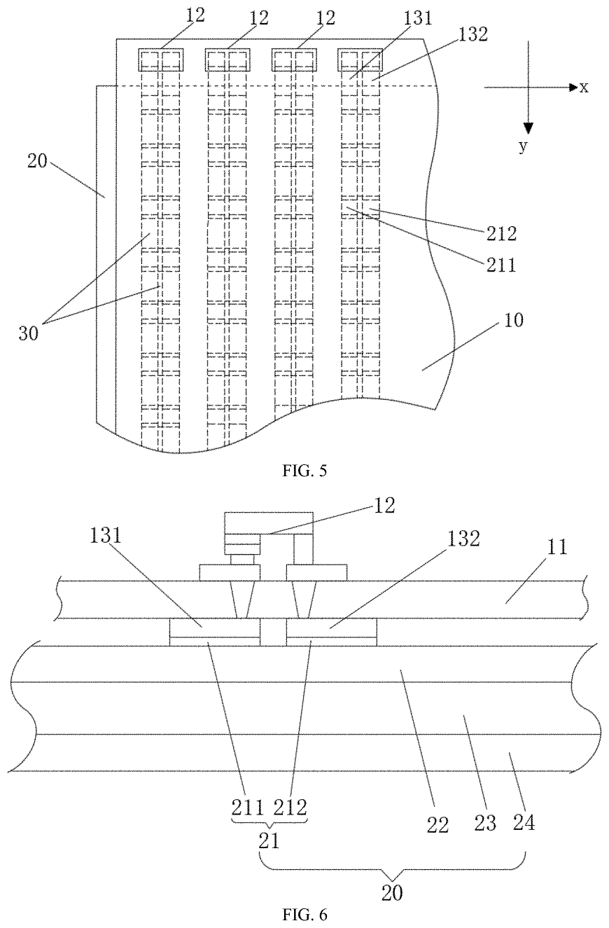

It should be noted that, in implementations of this disclosure, a width direction of the display backplane is a direction along x axis in FIG. 5 and a length direction of the display backplane is a direction along y axis in FIG. 5.

It should be noted that, in implementations of this disclosure, the light-emitting element may be an LED chip, the substrate is a printed circuit board (PCB). The LED chip used as the light-emitting element has a good light-emitting effect and is convenient for judgment. At the same time, the process of welding the LED chip on the PCB is simple and convenient for operation.

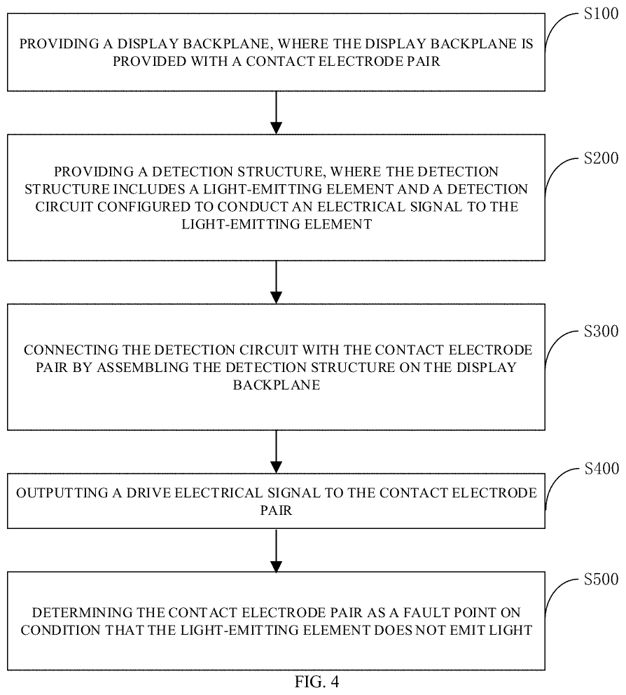

With reference to FIG. 4, a detection method for a display backplane 20 is provided in an implementation of this disclosure. The detection method begins at S100.

At S100, the display backplane 20 is provided, where the display backplane 20 is provided with a contact electrode pair 21.

At S200, a detection structure 10 is provided, where the detection structure 10 includes a light-emitting element 12 and a detection circuit 13 configured to conduct an electrical signal to the light-emitting element 12.

At S300, the detection circuit 13 is connected with the contact electrode pair 21 by assembling the detection structure 10 on the display backplane 20.

At S400, a drive electrical signal is outputted to the contact electrode pair 21.

At S500, the contact electrode pair 21 is determined as a fault point on condition that the light-emitting element 12 does not emit light.

According to the detection method of the disclosure, when the electrical signal is outputted to the contact electrode pair 21, the detection circuit 13 connected with the contact electrode pair 21 conducts the electrical signal to the light-emitting element 12. If the contact electrode pair 21 is a fault point, the electrical signal cannot be conducted on the detection circuit 13, so that the light-emitting element 12 will not emit light. In this case, it can be observed by human eyes that the position where the light-emitting element 12 does not emit light is a defective point on the display backplane 20. The detection process only requires to cover the detection structure 10 on the display backplane 20 and output the electrical signal, so that the detection speed is high and the detection result is obvious and easy to determine. In addition, the contact electrode pair 21 provided on the display backplane 20 is detected independently, which facilitates completion of quick detection and is convenient for possible subsequent repairing.

In an implementation, the method further includes S600 after S400. At S600, the contact electrode pair is determined to be normal on condition that the light-emitting element emits light.

As illustrated in FIG. 5, in an implementation, the detection structure 10 is assembled on the display backplane 20 as follows. A connection layer 30 is formed by applying glue to the display backplane 20 on one side provided with the contact electrode pairs 21. The detection structure 10 is covered on the connection layer 30 to fix the detection structure 10 to the display backplane 20 through the connection layer 30.

By gluing the display backplane 20 and the detection structure 10 with the connection layer 30, sliding can be avoided during the detection process. Therefore, misjudgment of a normal electrode pair as the fault point, which may be caused by separation of the detection circuit 13 and the contact electrode pair 21 so that the light-emitting element 12 does not emit light, can be reduced.

In an implementation, the detection method further includes the following. The display backplane 20 is flushed with a flushing agent to eliminate the connection layer 30 and the detection structure 10 is removed.

In this implementation, the connection layer 30 may include a photoresist layer. The photoresist has good adhesion on the display backplane 20 and the detection structure 10, thus having a good effect of fixation. In addition, the photoresist is nonconductive during the detection process, which can reduce the circuit fault. The flushing agent may include developer, and the photoresist can be removed quickly by flushing with the developer, which facilitates fast separation of the display backplane 20 and the detection structure 10. Furthermore, after flushing the photoresist will not remain on the display backplane 20 or the detection structure 10 and therefore will not damage the display backplane 20 or the detection structure 10.

As illustrated in FIG. 5, in an implementation, the contact electrode pair 21 is embodied as multiple contact electrode pairs 21 arranged in a rectangular array. The detection circuit 13 is embodied as multiple detection circuits 13. The light-emitting element 12 is embodied as multiple light-emitting elements 12. Each of the multiple detection circuits 13 is connected to at least one of the multiple light-emitting elements 12. The detection circuit 13 is connected with the contact electrode pair 21 as follows. The display backplane 20 is covered with the detection structure 10 to arrange the multiple detection circuits 13 along a width direction of the display backplane 20, where each detection circuit 13 is connected with one column of contact electrode pairs 21 along a length direction of the display backplane 20.

According to the display backplane 20 and the detection structure 10, during the detection process, an electrical signal is inputted row-by-row, and each contact electrode pair 21 in each row and column can be detected through a detection circuit 13 corresponding to the column. One detection circuit 13 is connected to all contact electrode pairs in the column along the length direction of the display backplane 20. The detection circuits 13 have a simple arrangement and the number of the light-emitting elements 12 required is small, which facilitates detection and reduce cost. In addition, the detection circuits 13 are separated from each other and therefore will not interfere with each other, which ensures accuracy of detection of the contact electrode pairs 21.

In an implementation, the glue is applied to the display backplane 20 on one side provided with the contact electrode pair 21 as follow. The glue is applied to the display backplane 20 at positions between any two neighboring rows of contact electrode pairs 21 of the multiple contact electrode pairs 21.

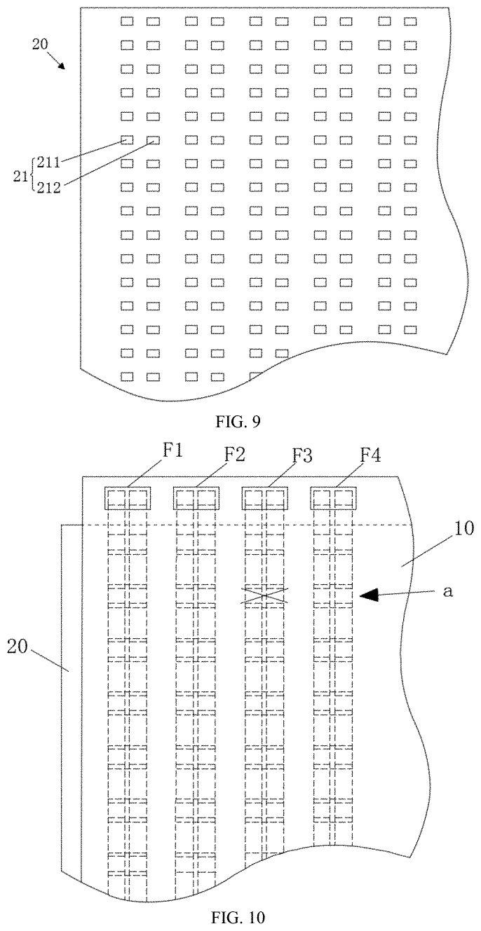

As illustrated in FIG. 9, there are multiple contact electrode pairs 21 on the display backplane 20 and the contact electrode pairs 21 protrude from the display backplane 20. When the detection structure 10 covers the display backplane 20, only the protruded detection circuits 13 are connected with the contact electrode pairs 21, leaving air space between the detection structure 10 and the display backplane 20. A shortest length of the air space is a distance from the detection circuit 13 to a surface of the display backplane 20. Disposing the connection layer 30 between the detection circuit 13 and the display backplane 20 can save materials to a greater extent. In addition, disposing the connection layer 30 between two neighboring contact electrode pairs 21 can realize a tighter connection between each of the contact electrode pairs 21 and the detection circuit 13 and reduce possibility of loosening of the connection. In this way, transmission of the electrical signal can be more accurate and smooth during the detection process.

In an implementation, the drive electrical signal is outputted to the contact electrode pair as follow. The drive electrical signal is outputted to the multiple contact electrode pairs row-by-row.

One detection circuit 13 is connected with a column of contact electrode pairs 21. When the drive electrical signal is outputted row-by-row, during one scanning, only one contact electrode pair 21 on the detection circuit 13 conducts the drive electrical signal, so that the detection is accurate and mutual interference will not occur.

In an implementation, the detection structure 10 is assembled on the display backplane 20 as follows. The display backplane 20 is covered with the detection structure 10 on one side of the display backplane 20 provided with the contact electrode pairs 21. The detection structure 10 is pressed in a direction of covering to fix the detection structure 10 to the display backplane 20.

The detection structure 10 and the display backplane 20 are fixed together through an applied pressure, which is direct, simple and easy to control. After completion of the detection process, the pressure can be removed immediately to separate the detection structure 10 from the display backplane 20, which can facilitate repairing or subsequent manufacturing process of the display backplane 20.

In an implementation, a first positioning structure is disposed on one side of the detection structure 10 towards the display backplane 20 and a second positioning structure is disposed on one side of the display backplane 20 at a position opposite to the first positioning structure. Each detection circuit 13 is aligned with the contact electrode pairs 21 when the first positioning structure is aligned with the second positioning structure. Before connecting the detection circuit 13 with the contact electrode pairs 21, the following is further executed. The detection structure 10 is moved to a position above the display backplane 20 to align the first positioning structure with the second positioning structure.

When the detection structure 10 covers on the display backplane 20, the detection circuit 13 faces the display backplane 20. Therefore, it is hard for human eyes to observe whether the detection circuit 13 is accurately connected with the contact electrode pairs 21. In this case, the first positioning structure and the second positioning structure can be pre-configured. For example, the first positioning structure and the second positioning structure can be disposed on the side surface of the detection structure 10 and the side surface of the display backplane 20. In this way, whether the detection circuit 13 is accurately aligned with the contact electrode pairs 21 can be determined by observing the first positioning structure and the second positioning structure. The subsequent detection process can thereby be proceeded smoothly and accurately.

According to the detection method of the disclosure, all contact electrode pairs 21 on the display backplane 20 are detected at one time through the covered detection structure 10. By scanning row-by-row, the operation status of the light-emitting element 12 are determined. As illustrated in FIG. 10, when the drive electrical signal is outputted to the contact electrode pair 21 in row a, the light-emitting elements 12F1, F2, F3, and F4 are conductive and whether they emit light is observed. For example, if the light-emitting element 12F3 does not emit light, the contact electrode pair 21 at a corresponding position “X” in row a in FIG. 10 is determined to be the fault point. The detection result is easy to determine and the operation is simple, which facilitates fast completion of the detection and speeds up the manufacturing process, reducing the time cost.

As illustrated in FIG. 5 and FIG. 8, according to another implementation of the disclosure, a detection structure 10 for a display backplane 20 is also provided. The detection structure 10 is configured to implement any of the detection method for the display backplane 20 described above. The detection structure 10 includes a substrate 11, a light-emitting element 12 disposed on the substrate 11, and a detection circuit 13 disposed on the substrate 11. The detection circuit 13 is connected with the light-emitting element 12 and is configured to receive a drive electrical signal and transmit the drive electrical signal to the light-emitting element 12

According to the detection structure 10 of the disclosure, during operation, the detection circuit 13 receives the drive electrical signal outputted from the contact electrode pair 21. If the contact electrode pair 21 is normal, the light-emitting element 12 will emit light. If the contact electrode pair 21 is a fault point, it cannot conduct the electrical signal and therefore the detection circuit 13 cannot transmit the electrical signal to the light-emitting element 12, so that the light-emitting element 12 will not emit light. In this case, it is possible for human eyes to observe a defect on the display backplane 20. The detection process only requires covering the detection structure 10 on the display backplane 20 and outputting the electrical signal. The detection result is obvious and easy to determine, and the operation is simple, which facilitates completion of quick detection and speeds up the manufacturing process, reducing the time cost.

In an implementation, the detection circuit 13 includes a first detection line 131 and a second detection line 132. The first detection line 131 is configured to conduct a positive electrical signal to the light-emitting element 12 and the second detection line 132 is configured to conduct a negative electrical signal to the light-emitting element 12. Alternatively, the second detection line 132 is configured to conduct the positive electrical signal to the light-emitting element 12 and the first detection line 131 is configured to conduct the negative electrical signal to the light-emitting element 12. The first detection line 131 is separated from the second detection line 132 and they conduct the electrical signals independently and will not interfere with each other. In this way, a circuit fault on the detection structure 10 can be reduced and the detection result can be more accurate.

In an implementation, the detection circuit 13 is embodied as multiple detection circuits 13 arranged side-by-side on the substrate 11. The multiple detection circuit 13 correspond to the multiple columns of contact electrode pairs 21 respectively. Through this arrangement, all contact electrode pairs 21 on the whole or a part of the display backplane 20 can be detected at one time, which improves the detection efficiency.

In an implementation, the detection circuits 13 are located at one side of the substrate 11 and the light-emitting elements 12 are located at another side of the substrate 11. The substrate 11 defines holes 111 and the detection circuits 13 are connected with the light-emitting elements 12 through the holes 111. In this implementation, the light-emitting elements 12 are disposed on the side of the substrate 11 away from the display backplane 20. On the one hand, when the detection structure 10 covers on the display backplane 20, the light-emitting elements 12 will not touch the display backplane 20 to avoid damage. On the other hand, when the display backplane 20 is placed with one side provided with multiple contact electrode pairs 21 facing upward, the detection structure 10 covers on the display backplane 20 and the light-emitting elements 12 emit light upward. In this way, it is convenient for human eyes to observe whether the light-emitting elements 12 emit light so that an accuracy of observation can be improved.

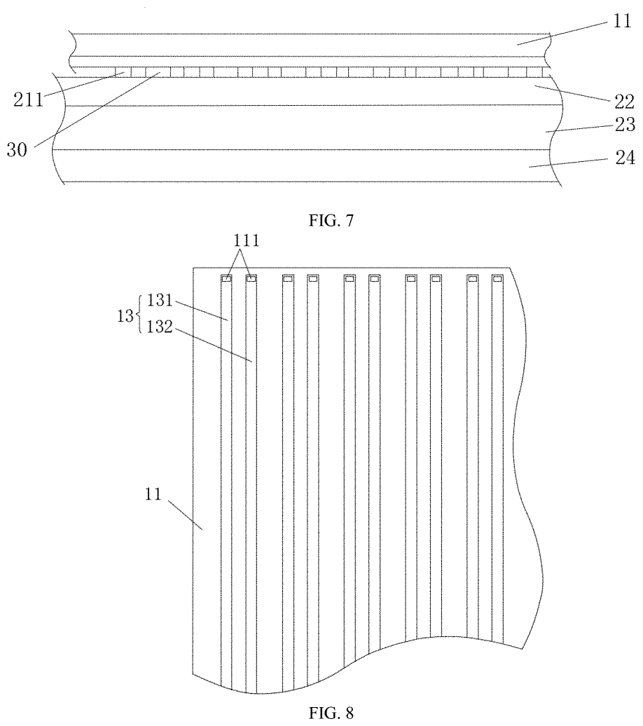

As illustrated in FIG. 6 and FIG. 7, in an implementation, the display backplane 20 includes a lower substrate 24, a circuit layer 23, and a planarization layer 22. The contact electrode pair includes a first contact electrode 211 and a second contact electrode 212. The detection circuit 13 includes a first detection line 131 and a second detection line 132 separated from the first detection line 131. One first detection line 131 is connected with one column of first contact electrode 211, and one second detection line 132 is connected with one column of second contact electrode 212. The first detection line 131 and the second detection line 132 are separated from each other to avoid short circuits during the detection process with the input electrical signals, so as to prevent the display backplane 20 from being damaged due to detection.

It should be understood that this disclosure is not limited to the accurate structure shown and described in the specification and drawings and many changes and modifications can be made without departing from the scope of the disclosure. The scope of the disclosure is defined and limited only by the appended claims.

The above descriptions are only some implementations of this disclosure and are not intended to limit this disclosure. Any modification, equivalent replacement, improvement, etc. made within the spirit and principle of this disclosure shall be included in the protection range of this disclosure.

What is claimed is:

1. A detection method for a display backplane, comprising:
providing the display backplane, wherein the display backplane is provided with a contact electrode pair;
providing a detection structure, wherein the detection structure comprises a light-emitting element and a detection circuit configured to conduct an electrical signal to the light-emitting element;
connecting the detection circuit with the contact electrode pair by assembling the detection structure on the display backplane;
outputting a drive electrical signal to the contact electrode pair; and
determining the contact electrode pair as a fault point on condition that the light-emitting element does not emit light.

2. The detection method of claim 1, further comprising:
after outputting the drive electrical signal to the contact electrode pair,
determining that the contact electrode pair is normal on condition that the light-emitting element emits light.

3. The detection method of claim 1, wherein assembling the detection structure on the display backplane comprises:
forming a connection layer by applying glue to the display backplane on one side provided with the contact electrode pair; and
covering the detection structure on the connection layer to fix the detection structure to the display backplane through the connection layer.

4. The detection method of claim 3, further comprising:
flushing the display backplane with a flushing agent to eliminate the connection layer and removing the detection structure.

5. The detection method of claim 1, wherein
the contact electrode pair is embodied as a plurality of contact electrode pairs arranged in a rectangular array, the detection circuit is embodied as a plurality of detection circuits, the light-emitting element is embodied as a plurality of light-emitting elements, each of the plurality of detection circuits is connected to at least one of the plurality of light-emitting elements, and connecting the detection circuit with the contact electrode pair comprises:
covering the display backplane with the detection structure to arrange the plurality of detection circuits along a width direction of the display backplane, wherein each detection circuit is connected with one column of contact electrode pairs along a length direction of the display backplane.

6. The detection method of claim 5, wherein applying glue to the display backplane on one side provided with the contact electrode pair comprises:
applying the glue to the display backplane at positions between any two neighboring rows of contact electrode pairs of the plurality of contact electrode pairs.

7. The detection method of claim 5, wherein outputting the drive electrical signal to the contact electrode pair comprises:
outputting the drive electrical signal to the plurality of contact electrode pairs row-by-row.

8. The detection method of claim 1, wherein assembling the detection structure on the display backplane comprises:
covering the display backplane with the detection structure on one side of the display backplane provided with the contact electrode pair; and
pressing the detection structure in a direction of covering to fix the detection structure to the display backplane.

9. The detection method of claim 1, wherein
a first positioning structure is disposed on one side of the detection structure towards the display backplane and a second positioning structure is disposed on one side of the display backplane at a position opposite to the first positioning structure; wherein the detection circuit is aligned with the contact electrode pair when the first positioning structure is aligned with the second positioning structure; and
the method further comprises:
prior to connecting the detection circuit with the contact electrode pair,
moving the detection structure to a position above the display backplane to align the first positioning structure with the second positioning structure.

10. A detection structure for a display backplane, configured to implement the detection method of claim 1 and comprising:
a substrate,
a light-emitting element disposed on the substrate, and
a detection circuit disposed on the substrate and connected with the light-emitting element, wherein the detection circuit is configured to receive a drive electrical signal and transmit the drive electrical signal to the light-emitting element.

11. The detection structure of claim 10, wherein the detection circuit comprises a first detection line and a second detection line, wherein
the first detection line is configured to conduct a positive electrical signal to the light-emitting element and the second detection line is configured to conduct a negative electrical signal to the light-emitting element; or
the second detection line is configured to conduct the positive electrical signal to the light-emitting element and the first detection line is configured to conduct the negative electrical signal to the light-emitting element.

12. The detection structure of claim 10, wherein the detection circuit is embodied as a plurality of detection circuits arranged side-by-side on the substrate.

13. The detection structure of claim 10, wherein the detection circuit and the light-emitting element are each located at one side of the substrate, wherein the substrate defines a hole and the detection circuit is connected with the light-emitting element through the hole.

14. A detection method for a display backplane, comprising:
providing the display backplane, wherein the display backplane is provided with contact electrode pairs;
providing a detection structure, wherein the detection structure comprises a light-emitting element and a detection circuit configured to conduct an electrical signal to the light-emitting element;
connecting the detection circuit with the contact electrode pairs by assembling the detection structure on the display backplane, wherein one detection circuit is connected with one column of contact electrode pairs;
outputting a drive electrical signal to the contact electrode pairs row-by-row; and
determining a contact electrode pair as a fault point on condition that the drive electrical signal is outputted to the contact electrode pair and the light-emitting element does not emit light.

15. The detection method of claim 14, wherein
the contact electrode pairs are arranged in a rectangular array;
the detection circuit is embodied as a plurality of detection circuits and the light-emitting element is embodied as a plurality of light-emitting elements, wherein each of the plurality of detection circuits is connected with at least one of the plurality of light-emitting elements; and
connecting the detection circuit with the contact electrode pairs comprises
covering the display backplane with the detection structure to arrange the plurality of detection circuits along a width direction of the display backplane, wherein one detection circuit is connected with one column of contact electrode pairs along a length direction of the display backplane.

16. The detection method of claim 14, further comprising:
after outputting the drive electrical signal to the contact electrode pairs row-by-row,
determining that a contact electrode pair is normal on condition that the drive electrical signal is outputted to the contact electrode pair and the light-emitting element emits light.

17. The detection method of claim 14, wherein assembling the detection structure on the display backplane comprises:
forming a connection layer by applying glue to the display backplane on one side provided with the contact electrode pairs; and
covering the detection structure on the connection layer to fix the detection structure to the display backplane through the connection layer.

18. The detection method of claim 17, further comprising:
flushing the display backplane with a flushing agent to eliminate the connection layer and removing the detection structure.

19. The detection method of claim 14, wherein assembling the detection structure on the display backplane comprises:
covering the display backplane with the detection structure on one side of the display backplane provided with the contact electrode pairs; and
pressing the detection structure in a direction of covering to fix the detection structure to the display backplane.

20. The detection method of claim 14, wherein
a first positioning structure is disposed on one side of the detection structure towards the display backplane and a second positioning structure is disposed on one side of the display backplane at a position opposite to the first positioning structure; wherein the detection circuit is aligned with the contact electrode pairs when the first positioning structure is aligned with the second positioning structure; and
the method further comprises:
prior to connecting the detection circuit with the contact electrode pair,
moving the detection structure to a position above the display backplane to align the first positioning structure with the second positioning structure.
